(19) United States
(12) Patent Application Publication
(10) Pub. No.: US 2017/0100926 A1
(43) Pub. Date: Apr. 13, 2017

(54) METHOD OF MANUFACTURING ELECTRONIC DEVICE AND COMPOSITE FILM

(71) Applicant: FUJIFILM Corporation, Tokyo (JP)

(72) Inventor: Kenji KANO, Minami-ashigara-shi (JP)

(73) Assignee: FUJIFILM Corporation, Tokyo (JP)

(21) Appl. No.: 15/386,169

(22) Filed: Dec. 21, 2016

Related U.S. Application Data
(63) Continuation of application No. PCT/JP2015/067756, filed on Jun. 19, 2015.

(30) Foreign Application Priority Data
Jun. 27, 2014 (JP) 2014-132989

(51) Int. Cl. B32B 38/00; B32B 7/12; H01L 51/52; B32B 37/12; H01L 51/56; B32B 7/06; B32B 23/08

(52) U.S. Cl. CPC B32B 38/164; B32B 7/06; B32B 7/12; B32B 23/08; B32B 37/12; H01L 51/56; H01L 51/5253; B32B 2307/7242; B32B 2457/206; B32B 2457/12; B32B 2038/166

(57) ABSTRACT

Provided is a method of manufacturing an electronic device including: drying a pressure sensitive adhesive layer of a composite film which has the pressure sensitive adhesive layer; and a first film and a second film bonded to each surface of the pressure sensitive adhesive layer and in which a moisture vapor transmission rate of the first film at a temperature of 40° C. and a relative humidity of 90% is 100 g/(m²·day) or greater; peeling the first film from the composite film in which the pressure sensitive adhesive layer is dried; and bonding the composite film from which the first film is peeled to an electronic device. In this manner, deterioration of the electronic device due to moisture can be prevented during the manufacture of a laminated electronic device formed by sealing the electronic device with a gas barrier film or the like.

### CROSS-REFERENCE TO RELATED APPLICATIONS

This application is a Continuation of PCT International Application No. PCT/JP2015/067756 filed on Jun. 19, 2015, which claims priority under 35 U.S.C. §119(a) to Japanese Patent Application No. 2014-132989 filed on Jun. 27, 2014. The above application is hereby expressly incorporated by reference, in its entirety, into the present application.

### BACKGROUND OF THE INVENTION

1. Field of the Invention

The present invention relates to a method of manufacturing an electronic device such as an organic EL device sealed by a gas barrier film or the like and a composite film used in the method of manufacturing the electronic device.

2. Description of the Related Art

Electronic devices which deteriorate due to moisture, such as organic EL devices or solar cells, are sealed by various sealing members. The electronic devices are typically sealed by glass. Meanwhile, for the purpose of weight reduction or improving impact resistance, sealing of electronic devices with plastic films has been examined.

Further, during the manufacture of an electronic device, a functional film exhibiting a target function such as a gas barrier film or an optical film may be bonded to the electronic device.

A composite film formed by bonding a film to both surfaces of a pressure sensitive adhesive layer is used to manufacture an electronic device that is obtained by sealing such an electronic device or bonding of a functional film thereto.

For example, JP2009-28946A describes a composite film, as a composite film (protective laminate) that seals an organic EL device, which includes a pressure sensitive adhesive layer; a protective film which is peelably and removably bonded to the pressure sensitive adhesive layer; and a deposited layer of an inorganic oxide, which has a surface base bonded to the pressure sensitive adhesive layer and having gas barrier properties and in which the surface base is formed on a transparent base, and in which the peel strength of the pressure sensitive adhesive layer is 100 mN/25 mm or less.

According to this composite film, handleability and workability are excellent, deterioration of gas barrier properties of the protective film due to the peeling is suppressed, and an organic EL device body is sealed by the surface base having gas barrier properties, thereby manufacturing an organic EL device.

Further, JP2014-25069A describes a composite film, as a composite film (base-less double-sided pressure sensitive adhesive sheet) used to manufacture an electronic device, which includes a peeling film respectively on both surfaces of a pressure sensitive adhesive layer, in which at least one peeling film has a configuration of a biaxially oriented polyester film, a coated layer, and a release agent layer formed in this order, in which the amount of oligomers on the surface of the release agent layer after the peeling film is heated at 180° C. for 10 minutes is 1.00 mg/m² or less.

According to this composite film, foreign matter resulting from the oligomers of a pressure sensitive adhesive layer can be reduced during manufacture of an electronic device that bonds functional films to each other using the pressure sensitive adhesive layer.

In the manufacture of an organic EL device using the composite film described in JP2009-28946A, first, the protective film is peeled from the composite film. Next, the composite film is directed toward the pressure sensitive adhesive layer and bonded to the organic EL device body having an organic EL element formed on the base. In this manner, the organic EL device body is sealed by the surface base or the gas barrier film to manufacture an organic EL device.

In the manufacture of an electronic device using the composite film described in JP2014-25069A, one peeling film is peeled and the functional film exhibiting a target function is bonded to the pressure sensitive adhesive layer. Next, the other peeling film is peeled and the composite film is directed to the pressure sensitive adhesive layer and bonded to the electronic device body having an electronic element formed on the base, thereby manufacturing an electronic device.

In such a method of manufacturing an electronic device of the related art, when an electronic device having an element deteriorating due to moisture, such as an organic EL device or a solar cell, is manufactured, an electronic device occasionally deteriorates due to the moisture contained in a pressure sensitive adhesive layer.

In order to avoid this disadvantage, drying of a pressure sensitive adhesive layer of a composite film before the composite film is bonded to an electronic device body is considered.

However, since a protective film or the like is bonded to the pressure sensitive adhesive layer of the composite film when a method of manufacturing an electronic device of the related art is used, drying of the pressure sensitive adhesive layer cannot be properly performed.

Moreover, bonding of a composite film to an electronic device body after a protective film or the like is peeled and a pressure sensitive adhesive layer is dried is considered.

However, in this manufacturing method, foreign matter adheres to the pressure sensitive adhesive layer which is exposed during the drying and thus defects or the like may occur in an electronic device due to the foreign matter.

In order to prevent adhesion of foreign matter to the pressure sensitive adhesive layer, the pressure sensitive adhesive layer needs to be dried in a highly cleaned atmosphere. Therefore, the cost of facilities and the production costs increase and the productivity is degraded.

### SUMMARY OF THE INVENTION

An object of the present invention is to solve the above-described problems of the related art and to provide a method of manufacturing an electronic device in which deterioration of the electronic device due to moisture can be prevented during the manufacture of the electronic device such as an organic EL device formed by sealing an organic EL device body with a gas barrier film so that an increase in production costs can be suppressed; and a composite film used for this manufacturing method.

In order to achieve the above-described object, according to the present invention, there is provided a method of manufacturing an electronic device comprising: a drying step of drying a pressure sensitive adhesive layer of a composite film which has the pressure sensitive adhesive layer, a first film bonded to one surface of the pressure sensitive adhesive layer, and a second film bonded to a surface of the pressure sensitive adhesive layer on the opposite side to the first film and in which a moisture vapor transmission rate of the first film at a temperature of 40° C. and a relative humidity of 90% is 100 g/(m²·day) or greater; a peeling step of peeling the first film from the composite film in which the pressure sensitive adhesive layer is dried; and a bonding step of bonding the composite film from which the first film is peeled to an electronic device body while facing the pressure sensitive adhesive layer toward the electronic device body.

In the method of manufacturing an electronic device of the present invention, it is preferable that the moisture vapor transmission rate of the second film at a temperature of 40° C. and a relative humidity of 90% is 1×10⁻³ g/(m²·day) or less.

Further, it is preferable that a pre-peeling step of peeling the second film from the composite film and a pre-bonding step of bonding a gas barrier film to the pressure sensitive adhesive layer of the composite film from which the second film is peeled are performed between the drying step and the peeling step and the peeling step is performed on the composite film to which the gas barrier film is bonded.

Further, it is preferable that the moisture vapor transmission rate of the gas barrier film at a temperature of 40° C. and a relative humidity of 90% is 1×10⁻³ g/(m²·day) or less.

Further, it is preferable that the electronic device body is an organic EL device body obtained by forming an organic EL element on a base.

According to the present invention, there is provided a composite film comprising: a pressure sensitive adhesive layer; a first film bonded to one surface of the pressure sensitive adhesive layer; and a second film bonded to a surface of the pressure sensitive adhesive layer on the opposite side to the first film, in which a moisture vapor transmission rate of the first film at a temperature of 40° C. and a relative humidity of 90% is 100 g/(m²·day) or greater.

In such a composite film of the present invention, it is preferable that the moisture vapor transmission rate of the second film at a temperature of 40° C. and a relative humidity of 90% is 1×10⁻³ g/(m²·day) or less.

Further, it is preferable that the second film includes a support and at least one combination of a gas barrier film and a smoothing film serving as a base of the gas barrier film, which is formed on the support.

Further, it is preferable that the gas barrier film is formed of any one of a nitride, an oxide, and an oxynitride.

Further, it is preferable that the first film includes a base film and a peeling layer formed on one surface of the base film.

Furthermore, it is preferable that the base film is a triacetyl cellulose film and the peeling layer has polydimethylsiloxane as a main component.

According to the present invention, it is possible to easily and reliably dry a pressure sensitive adhesive layer and to prevent adhesion of foreign matter to the pressure sensitive adhesive layer during the drying when an organic EL device in which an organic EL device body is sealed with a gas barrier film or the like having a pressure sensitive adhesive layer is manufactured. That is, the organic EL device body can be sealed by the composite film which does not have foreign matter adhering thereto and in which the pressure sensitive adhesive layer is reliably dried.

Therefore, according to the present invention, it is possible to stably manufacture a high-quality electronic device which does not have moisture, foreign matter, deterioration caused by moisture or foreign matter, or defects.

### BRIEF DESCRIPTION OF THE DRAWINGS

FIG. 1A is a flowchart for describing an example of a method of manufacturing an electronic device of the present invention and FIG. 1B is a flowchart for describing another example of a method of manufacturing an electronic device of the present invention.

FIG. 2 is a conceptual view for describing an example of a method of manufacturing an electronic device of the present invention and an example of a composite film of the present invention.

FIG. 3 is a conceptual view for describing another example of a method of manufacturing an electronic device of the present invention and another example of a composite film of the present invention.

FIG. 4A is a view conceptually illustrating an example of a first film of the composite film according to the present invention and FIG. 4B is a view conceptually illustrating an example of a gas barrier film used for the composite film according to the present invention.

### DESCRIPTION OF THE PREFERRED EMBODIMENTS

Hereinafter, a method of manufacturing an electronic device and a composite film of the present invention will be described in detail with reference to preferred examples illustrated in the accompanying drawings.

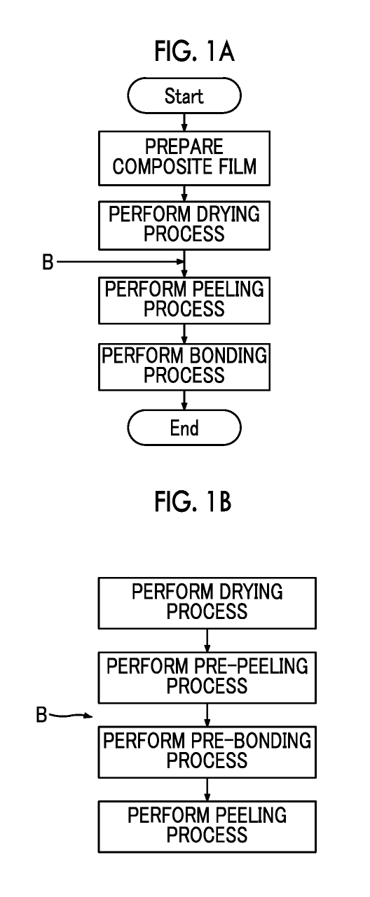

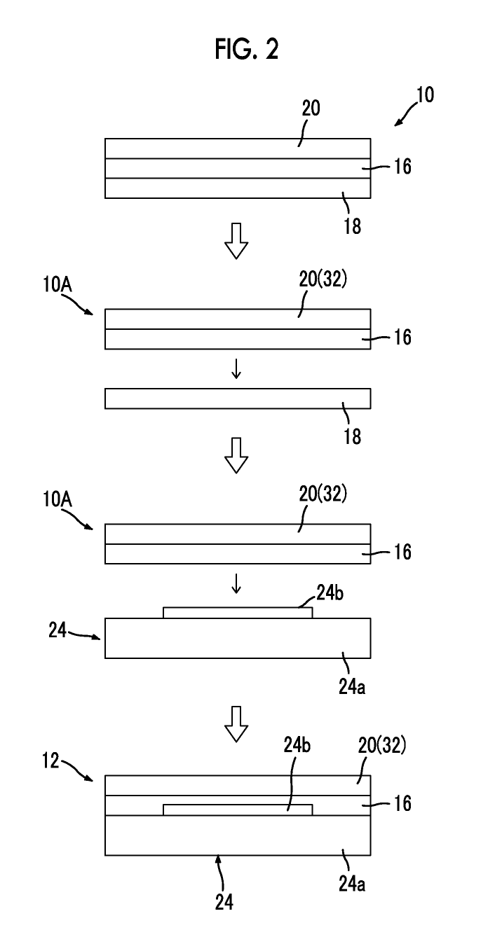

FIG. 1A is a flowchart for describing an example of the method of manufacturing an electronic device of the present invention. FIG. 2 conceptually illustrates the method of manufacturing an electronic device of the present invention corresponding to the flowchart of FIG. 1A.

The method of manufacturing an electronic device of the present invention illustrated in FIGS. 1A and 2 is a method of manufacturing an organic EL device 12 as an electronic device by preparing a composite film 10 and performing a drying step, a peeling step, and a bonding step. In the description below, the method of manufacturing an electronic device of the present invention is also simply referred to as a manufacturing method of the present invention.

Further, the example illustrated in FIGS. 1A and 2 is an example of applying the manufacturing method and the composite film 10 of the present invention to manufacture of the organic EL device 12. However, the present invention can be suitably applied to manufacture of various electronic devices. Specifically, the manufacturing method and the composite film of the present invention can be suitably applied to manufacture of electronic devices such as organic solar cells, organic transistors, liquid crystal displays, quantum dot displays, and electronic paper.

In the manufacturing method of the present invention, first, the composite film 10 is prepared. The composite film 10 is the composite film of the present invention, used for manufacturing method of the present invention.

As conceptually illustrated in FIG. 2, the composite film 10 includes a pressure sensitive adhesive layer 16, a first film 18, and a second film 20.

The pressure sensitive adhesive layer 16 is used for bonding the second film 20 or a functional film 32 described below to an organic EL device body 24 to seal the organic EL device body 24.

If the second film 20 or the functional film 32 described below can be bonded to the organic EL device body 24 with sufficient pressure sensitive adhesive force (adhesive force), various known pressure sensitive adhesives can be used as the pressure sensitive adhesive layer 16. Further, it is preferable that the pressure sensitive adhesive layer 16 has elasticity which can fill the level difference between or an organic EL element 24b and a base 24a.

Specific examples of the materials of forming the pressure sensitive adhesive layer 16 include pressure sensitive adhesives such as an acrylic acid ester resin, polyurethane, an acrylic resin, an ethylene-vinyl acetate copolymer (EVA), polyolefin, a silicone resin, and a rubber-based material.

The thickness of the pressure sensitive adhesive layer 16 may be appropriately set according to the type or characteristics of the pressure sensitive adhesive forming the pressure sensitive adhesive layer 16 and the configuration of the organic EL device body 24 (electronic device body) so that the second film 20 and the organic EL device body 24 can be reliably bonded to each other and the level difference between the organic EL element 24b and the base 24a is filled.

According to the examination of the present inventor, the thickness of the pressure sensitive adhesive layer 16 is preferably in a range of 0.5 to 200 μm and more preferably in a range of 3 to 60 μm.

The first film 18 is a film provided to protect the pressure sensitive adhesive layer 16 until the composite film 10 is bonded to the organic EL device body 24.

The first film 18 is peeled from the composite film 10 when the composite film 10 is bonded to the organic EL device body 24. Accordingly, a film which is bonded to the pressure sensitive adhesive layer 16 with excellent peeling properties (release properties) is preferable as the first film 18.

In the present invention, the moisture vapor transmission rate of the first film 18 at a temperature of 40° C. and a relative humidity of 90% is 100 g/(m²·day) or greater. In the description below, the moisture vapor transmission rate at a temperature of 40° C. and a relative humidity of 90% is also simply referred to as a moisture vapor transmission rate.

As will be described later, in the manufacturing method of the present invention, first, the pressure sensitive adhesive layer 16 of the composite film 10 is dried during the drying step in a state in which the first film 18 and the second film 20 are bonded. Thereafter, the first film 18 is peeled during the peeling step and a composite film 10A from which the first film 18 is peeled is bonded to the organic EL device body 24 during the bonding step.

Here, the moisture vapor transmission rate of the first film 18 is 100 g/(m²·day) or greater. Consequently, even when the pressure sensitive adhesive layer 16 is dried in the state in which the first film 18 and the second film 20 are bonded, the moisture vapor evaporated from the pressure sensitive adhesive layer 16 is released through the first film 18. Therefore, according to the manufacturing method of the present invention, the pressure sensitive adhesive layer 16 can be reliably dried in the state in which the first film 18 and the second film 20 are bonded. Further, since the pressure sensitive adhesive layer 16 is dried in the state in which the first film 18 and the second film 20 are bonded, it is possible to prevent adhesion of foreign matter to the pressure sensitive adhesive layer 16.

When the moisture vapor transmission rate of the first film 18 is less than 100 g/(m²·day), there are disadvantages that the pressure sensitive adhesive layer 16 is unlikely to be dried, the time for the drying step becomes longer in order to reliably dry the pressure sensitive adhesive layer 16, the conditions for the drying step need to be strict in order to reliably dry the pressure sensitive adhesive layer 16, and a load is applied to the pressure sensitive adhesive layer 16 or the second film 20.

In consideration of the above-described problems, the moisture vapor transmission rate of the first film 18 is preferably 200 g/(m²·day) or greater and more preferably 500 g/(m²·day) or greater.

Moreover, in the present invention, the moisture vapor transmission rate may be measured in conformity with JIS Z 0208-1976.

Various sheet-like materials can be used as the first film 18 as long as the moisture vapor transmission rate of the material is 100 g/(m²·day) or greater, the pressure sensitive adhesive layer 16 is covered so that the adhesion of foreign matter can be prevented, and the material can be bonded to the pressure sensitive adhesive layer 16 with excellent release properties.

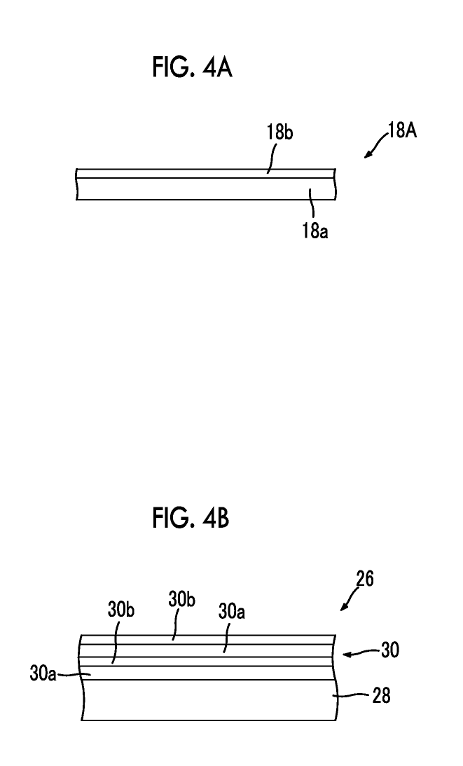

As an example, FIG. 4A conceptually illustrates a first film 18A obtained by forming a peeling layer 18b on a base film 18a serving as a body in order to provide release properties for the pressure sensitive adhesive layer 16.

If the moisture vapor transmission rate of the first film 18 can be set to 100 g/(m²·day) or greater, various films (sheet-like materials) can be used as the base film 18a and various known materials which are capable of providing release properties of a sheet-like material with respect to a pressure sensitive adhesive can be used as the peeling layer 18b.

In order to set the moisture vapor transmission rate of the first film 18 to 100 g/(m2·day) or greater, it is preferable that the base film 18a and the peeling layer 18b respectively have a high moisture vapor transmission rate.

Specific preferred examples of the first film 18 include films formed of triacetyl cellulose (TAC), diacetyl cellulose, nitrocellulose, and nylon.

Specific preferred examples of the peeling layer 18b include layers including polydimethylsiloxane (PDMS) and polyvinyl alcohol (PVA) as main components. Further, the peeling layer 18b may be formed using a known method such as a coating method depending on the formation materials or the like.

Among the examples, the first film 18 obtained by forming the peeling layer 18b, which includes PDMS as a main component, on a TAC film serving as the base film 18a is suitably used.

The thickness of the first film 18 which does not have the base film 18a and the peeling layer 18b may be appropriately set so as to sufficiently protect the pressure sensitive adhesive layer 16 according to the formation material of the first film 18 if the moisture vapor transmission rate thereof is 100 g/(m²·day) or greater.

According to the examination of the present inventor, the thickness of the base film 18a and the like is preferably in a range of 5 to 250 μm and more preferably in a range of 20 to 120 μm.

Moreover, the thickness of the peeling layer 18b may be appropriately set according to the formation material of the peeling layer 18b so that release properties can be sufficiently provided.

In the composite film 10, the second film 20 is bonded to the surface of the pressure sensitive adhesive layer 16 on the opposite side to the first film 18.

Various known film-like materials can be used as the second film 20.

It is preferable that the second film 20 is a film exhibiting a target function when became a part of the organic EL device 12.

As the second film 20, a film having gas barrier properties with a moisture vapor transmission rate of 1×10⁻³ g/(m²·day) or less is preferable. In addition, the moisture vapor transmission rate of the present invention indicates a moisture vapor transmission rate at a temperature of 40° C. and a relative humidity of 90% as described above. As the second film 20 having a moisture vapor transmission rate of 1×10⁻³ g/(m²·day) or less, a so-called gas barrier film obtained by forming a gas barrier layer on a support may be preferably exemplified.

Moreover, other than the gas barrier film, functional films exhibiting various functions can be used as the second film 20 exhibiting a target function.

Examples thereof include optical films such as a color film (color filter), an anti-reflection film, and a polarizing film; and functional films such as a protective film used to protect an organic EL device from mechanical damage.

Among these, from the viewpoint of obtaining the maximum effect of drying the pressure sensitive adhesive layer 16, a gas barrier film may be preferably exemplified as the second film 20. More specifically, a gas barrier film having a moisture vapor transmission rate of 1×10⁻³ g/(m²·day) or less may be preferably exemplified as the second film 20.

Various known films can be used as the gas barrier film used as the second film 20.

Among various known films, an organic/inorganic laminate type gas barrier film having one or more combinations of an inorganic film exhibiting gas barrier properties and an organic film serving as a base of the inorganic film, as a gas barrier layer, on a support is suitably used as the second film 20.

FIG. 4B conceptually illustrates an example of a gas barrier film which can be used as the second film 20. Further, the gas barrier film 26 is suitably used as the functional film 32 described below.

The gas barrier film 26 illustrated in FIG. 4B has a configuration in which the gas barrier layer 30 is formed on the support 28. Further, the gas barrier layer 30 is formed of an inorganic film 30b exhibiting gas barrier properties and an organic film 30a, as a base of the inorganic film 30b, used to flatten the surface on which the inorganic film 30b is formed.

In the gas barrier film 26 illustrated in FIG. 4B, the gas barrier layer 30 has a four-layer structure configured of the organic film 30a formed on the support 28; the inorganic film 30b formed on the organic film 30a; the organic film 30a formed on the inorganic film 30b; and the inorganic film 30b formed on the organic film 30a. That is, the gas barrier layer 30 has two combinations of the organic film 30a as a base and the inorganic film 30b.

Moreover, in addition to the configuration having two combinations of the organic film 30a as a base and the inorganic film 30b in the gas barrier film used in the present invention as illustrated in the figure, various configurations can be used as the configuration of the gas barrier layer 30 as long as the configuration has one or more combinations of the organic film 30a as a base and the inorganic film 30b.

For example, the gas barrier layer may have a two-layer configuration having only one combination of the organic film 30a as a base and the inorganic film 30b. Alternatively, the gas barrier layer may have a configuration of six or more layers, that is, three or more combinations of the organic film 30a as a base and the inorganic film 30b. Further, the gas barrier layer may have a configuration in which an inorganic film is formed on the support 28 and one or more combinations of the organic film 30a as a base and the inorganic film 30b are formed on the inorganic film.

In the gas barrier film 26 illustrated in FIG. 4B, various known sheet-like materials being used as supports of a gas barrier film can be used as the support 28.

Specific preferred examples of the support 28 include plastic films formed of various plastics (polymer materials) such as polyethylene terephthalate (PET), polyethylene naphthalate (PEN), polyethylene (PE), polypropylene (PP), polystyrene, polyamide, polyvinyl chloride, polycarbonate, polyacrylonitrile, polyimide, polyacrylate, polymethacrylate, polycarbonate (PC), a cycloolefine polymer (COP), a cycloolefine copolymer (COC), triacetyl cellulose (TAC),1 and transparent polyimide.

The inorganic film 30b is a film mainly exhibiting gas barrier properties of the gas barrier film 26.

As the formation material of the inorganic film 30b, various layers formed of inorganic compounds exhibiting gas barrier properties can be used. Among various examples, nitrides, oxides, and oxynitrides are suitably used.

Specific preferred examples thereof include inorganic compounds, for example, metal oxides such as aluminum oxide, magnesium oxide, tantalum oxide, zirconium oxide, titanium oxide, and indium tin oxide (ITO); metal nitrides such as aluminum nitride; metal carbides such as aluminum carbide; silicon oxides such as silicon oxide, silicon oxynitride, silicon oxycarbide, and silicon oxynitride carbide; silicon nitrides such as silicon nitride and silicon carbide nitride; silicon carbides such as silicon carbide; hydrides of these; mixtures of two or more of these; and hydrogen-containing materials.

Particularly, from the viewpoints of excellent transparency and exhibiting excellent gas barrier properties, silicon nitride, silicon oxide, silicon oxynitride, and aluminum oxide are suitably used. Among these, particularly, silicon nitride has excellent transparency in addition to excellent gas barrier properties and thus is suitably used.

The organic film 30a is obtained by crosslinking (polymerizing) an organic compound which becomes the organic film 30a with a layer formed of an organic compound.

The organic layer 30a functions as a base layer used to properly form the inorganic film 30b exhibiting gas barrier properties. When the gas barrier film has the organic film 30a as a base, a state suitable for forming the inorganic film 30b can be obtained by flattening and uniformizing the surface on which the inorganic film 30b is formed.

In the laminate type gas barrier film in which the organic film 30a as a base and the inorganic film 30b are laminated with each other, the appropriate inorganic film 30b can be formed on the entire surface of a film without any space left and a gas barrier film having excellent gas barrier properties can be obtained.

Various known organic compounds (resins/polymer compounds) can be used as the formation material of the organic film 30a.

Specific preferred examples thereof include thermoplastic resins such as polyester, an acrylic resin, a methacrylic resin, a methacrylic acid-maleic acid copolymer, polystyrene, a transparent fluororesin, polyimide, fluorinated polyimide, polyamide, polyamideimide, polyetherimide, cellulose acylate, polyurethane, polyether ether ketone, polycarbonate, alicyclic polyolefin, polyarylate, polyether sulfone, polysulfone, fluorene ring-modified polycarbonate, alicyclic-modified polycarbonate, fluorene ring-modified polyester, and an acryloyl compound; polysiloxane; and films of other organic silicon compounds. These may be used in a combination of plural kinds thereof.

Among the examples, from the viewpoints of the excellent glass transition temperature and strength, the organic film 30a formed of a polymer of a cationically polymerizable compound having a radically polymerizable compound and/or an ether group in a functional group is preferable.

Among the examples, from the viewpoints of the low refractive index, excellent transparency, and excellent optical characteristics, an acrylic resin or a methacrylic resin which includes a polymer of an oligomer or a monomer of acrylate and/or methacrylate as a main component and has a glass transition temperature of 120° C. or higher is particularly preferably exemplified as the organic film 30a.

Among these, an acrylic resin or a methacrylic resin having a polymer such as a monomer of di- or higher functional acrylate and/or methacrylate as a main component, such as dipropylene glycol di(meth)acrylate (DPGDA), 1,9-nonanediol di(meth)acrylate (A-NOD-N), 1,6-hexanediol diacrylate (A-HD-N), trimethylolpropane tri(meth)acrylate (TMPTA), (modified) bisphenol A di(meth)acrylate, or dipentaerythritol hexa(meth)acrylate (DPHA), is particularly preferably exemplified. Further, it is preferable to use a plurality of acrylic resins and methacrylic resins.

When the organic film 30a is formed using an acrylic resin or a methacrylic resin and particularly a di- or higher functional acrylic resin or methacrylic resin, since the inorganic film 30b can be formed on a base having a firm skeleton, the inorganic film 30b which is denser and has excellent gas barrier properties can be formed.

In the composite film 10, various known films (sheet-like materials) can be used as the second film 20 in addition to functional films such as the gas barrier film 26.

For example, the second film 20 may have a peeling layer similar to the first film 18 and may be peeled from the composite film 10 before the organic EL device body 24 is sealed.

Accordingly, the second film 20 may be the same as the first film 18.

Alternatively, the second film 20 may be a PET film a PEN film or a PE film formed with a peeling layer. At this time, the moisture vapor transmission rate of the second film 20 may be 100 g/(m²·day) or greater or less than 100 g/(m²·day).

If the second film 20 is a functional film such as a gas barrier film, the second film 20 may have a thickness capable of exhibiting a target function depending on the configuration of the film.

Further, in a case where the second film 20 is peeled, the thickness thereof may be appropriately set so that the pressure sensitive adhesive layer 16 is sufficiently operated as a protective film according to the formation material or the like.

Such a composite film 10 may be prepared using a known method according to the formation material of the pressure sensitive adhesive layer 16 and the formation materials of the first film 18 and the second film 20.

As an example, a method of preparing the composite film 10 by coating the surface of the first film 18 with a coating material (composition) which becomes the pressure sensitive adhesive layer 16, laminating the second film 20 on the coating material, and curing the coating material using a method in accordance with the formation material of the pressure sensitive adhesive layer 16 may be exemplified. At this time, in a case where the first film 18 and/or the second film 20 have a peeling layer, the peeling layer is allowed to face the pressure sensitive adhesive layer 16.

As illustrated in FIGS. 1A and 2, according to the manufacturing method of the present invention, the pressure sensitive adhesive layer 16 of the composite film 10 is dried during the drying step when such a composite film 10 is prepared.

In the manufacturing method of the present invention, as described above, the first film 18 of the composite film 10, which is bonded to the pressure sensitive adhesive layer 16 has a moisture vapor transmission rate of 100 g//(m²·day) or greater.

Therefore, since the moisture vapor released from the pressure sensitive adhesive layer 16 due to the drying is discharged outside through the first film 18, the pressure sensitive adhesive layer 16 can be reliably dried. Further, because of the presence of the first film 18, it is possible to prevent adhesion of foreign matter to the pressure sensitive adhesive layer 16.

The pressure sensitive adhesive layer 16 may be dried during the drying step according to a known method such as heating drying, drying under reduced pressure, or heating drying under reduced pressure.

Further, during the drying step, it is preferable that the pressure sensitive adhesive layer 16 is dried until the moisture content of the pressure sensitive adhesive layer 16 becomes 200 ppm or less and more preferable that the pressure sensitive adhesive layer 16 is dried until the moisture content of the pressure sensitive adhesive layer 16 becomes 100 ppm or less. In this manner, deterioration of an organic EL device due to moisture can be more suitably suppressed.

Accordingly, the conditions for carrying out drying during the drying step may be appropriately set according to the formation materials of the first film 18 and the pressure sensitive adhesive layer 16.

After the drying step is finished, the peeling step of peeling the first film 18 from the composite film 10 is performed. The first film 18 may be peeled from the composite film 10 according to a known method.

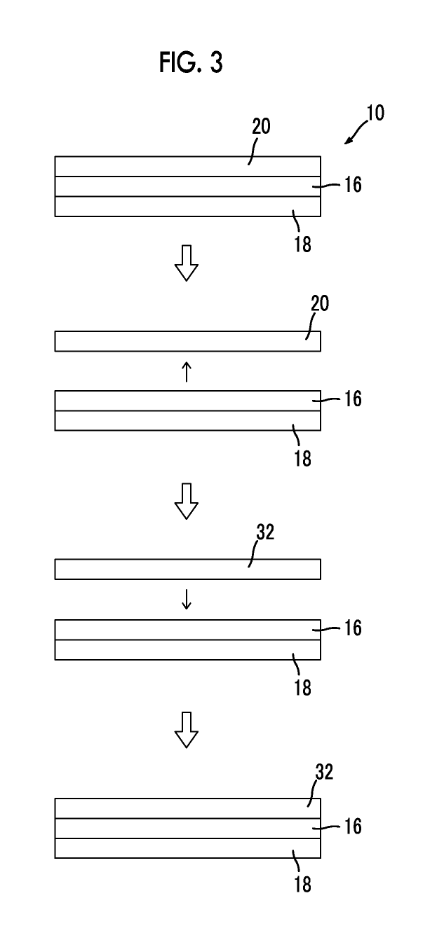

Here, in a case where the second film 20 is peeled from the composite film 10, such as a case where the second film 20 is the same as the first film 18 or a case where the second film is a film in which a peeling layer is formed on a PET film, a process B shown in the flowchart of FIG. 1B and the conceptual view of FIG. 3 is performed after the drying step and then the peeling step is performed.

At this time, as illustrated in FIGS. 1B and 3, a pre-peeling step of peeling the second film 20 from the composite film 10 in which the drying step is finished is firstly performed. The second film 20 may be peeled from the composite film 10 according to a known method.

Next, as illustrated in FIGS. 1B and 3, a pre-bonding step of bonding the functional film 32, which exhibits a target function such as gas barrier properties, to the pressure sensitive adhesive layer 16 from which the second film 20 is peeled is performed.

Various functional films exemplified in the above-described second film 20, such as the gas barrier film 26 and an optical film, can be suitably used as the functional film 32. Among the examples, from the viewpoint of obtaining the maximum effect of drying the pressure sensitive adhesive layer 16, a gas barrier film is preferably used as the functional film 32. More specifically, a gas barrier film having a moisture vapor transmission rate of 1×10⁻³ g/(m²·day) or less is particularly preferably used as the functional film 32.

During the pre-bonding step, the functional film 32 may be bonded using a known method of laminating, pressure bonding, or pressure bonding under heating according to the formation material or the like of the pressure sensitive adhesive layer 16.

Moreover, in a case where the second film 20 is peeled from the composite film 10, the pre-peeling step and the pre-bonding step may be performed before the drying step.

At this time, after the composite film 10 is prepared, first, the pre-peeling step of peeling the second film is performed, the pre-bonding step of bonding the functional film 32 to the pressure sensitive adhesive layer 16 is performed, and then the drying step and the peeling step are performed.

When the peeling step is finished, as illustrated in FIGS. 1A and 2, the bonding step of bonding the composite film 10A from which the first film 18 is peeled to the organic EL device body 24 while facing the pressure sensitive adhesive layer 16 toward the organic EL device body 24 is performed.

The organic EL device body 24 is obtained by forming one or more organic EL elements 24b on the surface of the base 24a such as a glass plate or a metal plate having an insulating layer.

When the bonding step is performed, the organic EL device 12 formed by sealing the organic EL device body 24 with the second film 20 or the functional film 32 such as a gas barrier film is manufactured.

Here, in the manufacturing method of the present invention, as described above, the pressure sensitive adhesive layer 16 is suitably dried and adhesion of foreign matter to the pressure sensitive adhesive layer 16 is suppressed. Therefore, the organic EL device 12 manufactured by the present invention is a high-quality organic EL device 12 in which deterioration due to moisture is suppressed and which does not have defects resulting from foreign matter.

According to the manufacturing method of the present invention, the composite film 10A from which the first film 18 is peeled may be bonded to the organic EL device body 24 using a known method of laminating, pressure bonding, or pressure bonding under heating in accordance with the formation material or the like of the pressure sensitive adhesive layer 16.

As described above, the manufacturing method of the present invention can be used to manufacture various electronic devices in addition to the organic EL device 12. Therefore, an organic solar cell body obtained by forming one or more photoelectric conversion elements on a base; an organic transistor body obtained by forming one or more organic transistor elements on a base; a liquid crystal display body obtained by forming one or more liquid crystal shutters on a base; a quantum dot display body obtained by forming one or more quantum dot elements on a base; or an electronic paper body obtained by forming one or more display elements on a base can be used as the electronic device body.

Here, from the viewpoint that deterioration of an electronic device due to moisture can be more suitably prevented by drying the pressure sensitive adhesive layer 16, the manufacturing method of the present invention is suitably used to manufacture the organic EL device 12 illustrated in the figure.

As described above, the manufacturing method of the present invention includes the drying step, the peeling step, and the bonding step. Here, according to the manufacturing method of the present invention, in order to prevent moisture absorption of the pressure sensitive adhesive layer 16 dried during the drying step, it is preferable that the drying step, the peeling step, and the bonding step are performed in an atmosphere in which the dew point is controlled. This controlling of atmosphere includes controlling of the atmosphere of an environment in which a composite film is transported during each of the processes of the drying step, the peeling step, and the bonding step.

Specifically, it is preferable that the drying step, the peeling step, and the bonding step are performed in an atmosphere in which the dew point is controlled to −40° C. or lower and more preferable that that the drying step, the peeling step, and the bonding step are performed in an atmosphere in which the dew point is controlled to −60° C. or lower. In this manner, deterioration of the organic EL device due to moisture can be suitably suppressed.

In a case where the pre-peeling step and the pre-bonding step are performed between the time period of the drying step, the peeling step, and the bonding step, it is preferable that these processes are performed in an atmosphere in which the dew point is controlled to be low.

Hereinbefore, the method of manufacturing an electronic device and the composite film of the present invention have been described, but the present invention is not limited to the above-described examples and various improvements and modifications can be made in the range not departing from the scope of the present invention.

### EXAMPLES

Hereinafter, the present invention will be described in detail with reference to specific examples of the present invention.

<Preparation of Gas Barrier Film>

A PEN film (TEONEX Q65FA, manufactured by Teijin DuPont Films Japan Limited) was prepared as the support 28.

TMPTA (manufactured by Daicel-Cytec Company LTD.), a silane coupling agent (KBM-5103, manufactured by Shin-Etsu Chemical Co., Ltd.), and a polymerizable acidic compound (KARAMER PM-21, manufactured by Nippon Kayaku Co., Ltd.) were mixed with each other at a mass ratio of 14.1:3.5:1, thereby preparing a composition.

18.6 g of this composition, 1.4 g of an ultraviolet polymerization initiator (ESACURE KTO46, manufactured by Lamberti S. P. A), and 180 g of 2-butanone were mixed with each other to prepare a coating material for forming the organic film 30a.

The surface of the prepared support 28 (PEN film) was coated with the prepared coating material. The surface thereof was coated using a wire bar such that the coated film thickness became 5 μm.

Next, after the coating material was dried at room temperature for 5 minutes, the composition of the coating material was cured by irradiating (integrated irradiation dose of approximately 1 J/cm²) the coating material with ultraviolet rays of a high pressure mercury lamp in a chamber in which the oxygen concentration was set to 0.1% according to a dry nitrogen substitution method. In this manner, the organic film 30a having a thickness of 600 nm±50 nm was formed on the surface of the support 28.

A silicon nitride film having a thickness of 40 nm was formed on the organic film 30a as the inorganic film 30b.

The inorganic film 30b (silicon nitride film) was formed using a typical CCP (capacitively coupled plasma method)-CVD device. As raw material gas, silane gas (flow rate of 160 sccm), ammonia gas (flow rate of 370 sccm), hydrogen gas (flow rate of 590 sccm), and nitrogen gas (flow rate of 240 sccm) were used. The deposition pressure was set to 40 Pa. A high frequency power source having a frequency of 13.56 MHz was used as a power source and the plasma excitation power was set to 2.5 kW.

The organic film 30a having a thickness of 600 nm±50 nm was formed on this inorganic film 30b in the same manner as described above and a silicon nitride film having a thickness of 40 nm was formed on this organic film 30a as the inorganic film 30b in the same manner as described above.

In this manner, the gas barrier film 26 in which the gas barrier layer 30 having two combinations of the organic film 30a serving as a base and the inorganic film 30b was formed on the surface of the support 28 was prepared as shown in FIG. 4B.

The moisture vapor transmission rate of the gas barrier film 26 which was measured in conformity with JIS Z 0208-1976 was 1×10⁻³ g/(m²·day) or less.

<Preparation of Organic EL Device Body>

A conductive glass substrate (surface electrical resistance of 10Ω/□) having an ITO film was washed with 2-propanol and then a UV-ozone treatment was performed for 10 minutes. The following organic compound layers were sequentially deposited on the substrate (anode) according to a vacuum deposition method.

| | |
|---|---|
| (First positive hole transport layer) | |
| Copper phthalocyanine | film thickness of 10 nm |
| (Second positive hole transport layer) | |
| N,N′-diphenyl-N,N′-dinaphthylbenzidine | film thickness of 40 nm |
| (Light-emitting layer/electron transport layer) | |
| Tris(8-hydroxyquinolinato) aluminum | film thickness of 60 nm |

Finally, lithium fluoride having a thickness of 1 nm and metal aluminum having a thickness of 100 nm were sequentially deposited to obtain a cathode and a silicon nitride film having a thickness of 5 μm was formed thereon according to a parallel plate type CCP-CVD method.

In this manner, the organic EL device body 24, illustrated in FIG. 2, formed by preparing the organic EL element 24b was prepared on the surface of a glass substrate as the base 24a.

### Example 1

As the first film 18 and the second film 20, a film obtained by forming a PDMS film having a thickness of 5 μm on the surface of a TAC film having a thickness of 40 μm as a peeling layer was prepared respectively.

The moisture vapor transmission rate of the first film 18 which was measured in conformity with JIS Z 0208-1976 was 2050 g/(m²·day).

The peeling layer of the first film 18 was coated with a liquid resin (SK DYNE 1831, manufactured by Soken Chemical & Engineering Co., Ltd.) of two-liquid thermosetting type acrylic ester. The liquid resin was applied using an applicator.

Next, the peeling layer was directed toward the liquid resin, the second film 20 was laminated, and the liquid resin was cured at 80° C. for 30 minutes, thereby preparing the composite film 10 obtained by bonding the first film 18 and the second film 20 to the pressure sensitive adhesive layer 16 having a thickness of 20 μm.

The composite film 10 was put into a glove box in which the dew point was adjusted to −60° C. Further, all the subsequent processes were performed in the glove box in which the dew point was adjusted to −60° C.

The composite film 10 which was put into the glove box was subjected to a heat treatment at 80° C. for 24 hours and then the pressure sensitive adhesive layer 16 was dried.

The composite film 10 was cooled to room temperature and then the second film 20 was peeled. Next, the gas barrier layer 30 was directed toward the pressure sensitive adhesive layer 16 and the gas barrier film 26 prepared in advance was bonded to the pressure sensitive adhesive layer 16.

Subsequently, the first film 18 was peeled. Further, the pressure sensitive adhesive layer 16 was directed toward the organic EL element 24b, the composite film 10A from which the first film 18 was peeled was bonded to the organic EL device body 24 prepared in advance, and then the organic EL device 12, illustrated in FIG. 2, obtained by sealing the organic EL device body 24 with the composite film 10A having the gas barrier film 26 and the pressure sensitive adhesive layer 16 was prepared.

### Example 2

The composite film 10 was prepared in the same manner as in Example 1 except that the gas barrier layer 30 was directed toward the pressure sensitive adhesive layer 16 and the gas barrier film 26 was bonded to the pressure sensitive adhesive layer 16 using the gas barrier film 26 prepared in advance as the second film 20.

The composite film 10 was put into a glove box in which the dew point was adjusted to −60° C. Further, all the subsequent processes were performed in the glove box in which the dew point was adjusted to −60° C.

The composite film 10 which was put into the glove box was subjected to a heat treatment in the same manner as in Example 1 and then the pressure sensitive adhesive layer 16 was dried.

The composite film 10 was cooled to room temperature and then the first film 18 was peeled. Next, the composite film 10A from which the first film 18 was peeled was bonded to the organic EL device body 24 prepared in advance, and then the organic EL device 12, illustrated in FIG. 2, obtained by sealing the organic EL device body 24 with the composite film 10A having the gas barrier film 26 and the pressure sensitive adhesive layer 16 was prepared in the same manner as in Example 1.

### Example 3

The organic EL device 12 was prepared in the same manner as in Example 1 except that the second film 20 of the composite film 10 was made into a film obtained by forming a film of an ethylene-vinyl acetate (EVA) copolymer having a thickness of 5 μm on the surface of a PET film having a thickness of 50 m as a peeling layer.

### Comparative Example 1

The organic EL device 12 was prepared in the same manner as in Example 1 except that the first film 18 and the second film 20 of the composite film 10 were made into films respectively obtained by forming an EVA film having a thickness of 5 μm on the surface of a PET film having a thickness of 50 μm as a peeling layer.

The moisture vapor transmission rate of the first film 18 which was measured in conformity with JIS K 7129-2008 was 15 g/(m²·day).

### Comparative Example 2

The organic EL device 12 was prepared in the same manner as in Example 2 except that the first film 18 of the composite film 10 was made into the same film as in Comparative Example 1.

### Comparative Example 3

The organic EL device 12 was prepared in the same manner as in Comparative Example 2 except that the composite film was put into a glove box, the first film 18 was peeled therefrom, the pressure sensitive adhesive layer 16 was dried by performing a heat treatment on the composite film, and then the composite film 10A was bonded to the organic EL device body 24.

<Evaluation (OLED Test)>

The organic EL device 12 prepared in this manner was allowed to stand in an environment of 60° C. for 24 hours. In this environment, humidification was not performed.

Thereafter, the organic EL device 12 was allowed to emit light by applying a voltage of 7 V using an SMU2400 type source-measure unit (manufactured by Keithley Inc.), the light emitting surface was observed using a microscope, and the size of dark spots was evaluated.

A case where dark spots in which the diameters of circles being circumscribed were 300 μm or greater were not able to be confirmed was evaluated as excellent and a case where the diameters of circles being circumscribed were greater than 300 μm were confirmed was evaluated as impossible.

The results are listed in the following table.

TABLE 1

| | | | | | Comparative | Comparative | Comparative |
|---|---|---|---|---|---|---|---|
| | | Example 1 | Example 2 | Example 3 | Example 1 | Example 2 | Example 3 |
| Second film | Base film | TAC | Gas barrier | PET | PET | Gas barrier | PET |
| | Peeling layer | PDMS | film | EVA | EVA | film | EVA |
| Pressure sensitive adhesive layer | | Two-liquid thermosetting type acrylic ester | | | | | |
| First film | Base film | TAC | TAC | TAC | PET | PET | PET |
| | Peeling layer | PDMS | PDMS | PDMS | EVA | EVA | EVA |
| | Moisture vapor | 2050 | 2050 | 2050 | 15 | 15 | 15 |
| | transmission rate | | | | | | |

| | | | | | | |
|---|---|---|---|---|---|---|
| OLED test | Excellent | Excellent | Excellent | Impossible | Impossible | Impossible |

In Comparative Example 3, the drying step was performed after the first film was peeled

The unit of the moisture vapor transmission rate was [g/(m²·day)]

As listed in Table 1, the organic EL device 12 manufactured by the manufacturing method of the present invention in which the moisture vapor transmission rate of the first film 18 was 2050 g/(m²·day) is a high-quality organic EL device which does not have dark spots in which the diameters of circles being circumscribed are 300 μm or greater.

Meanwhile, in Comparative Examples 1 and 2 in which the moisture vapor transmission rate of the first film is 15 g/(m²·day), it is considered that the pressure sensitive adhesive layer 16 was not able to be properly dried during the drying step so that the organic EL element deteriorated due to moisture discharged from the pressure sensitive adhesive layer 16 when allowed to stand in an environment of 60° C. for 24 hours and thus dark spots in which the diameters of circles being circumscribed are 300 μm or greater were generated.

Further, in Comparative Example 3 in which the drying step was performed after the first film was peeled, it is considered that the pressure sensitive adhesive layer 16 was properly dried, but foreign matter was adhered to the pressure sensitive adhesive layer 16 during the drying step so that the organic EL element deteriorated due to the foreign matter and thus dark spots in which the diameters of circles being circumscribed are 300 μm or greater were generated.

From the above-described results, the effects of the present invention are evident.

### INDUSTRIAL APPLICABILITY

The present invention can be suitably applied to manufacture of electronic devices such as organic EL devices.

### EXPLANATION OF REFERENCES

10: composite film
12: organic EL device
16: pressure sensitive adhesive layer
18: first film
18a: base film
18b: peeling layer
20: second film
24: organic EL device body
24a: base
24b: organic EL element
26: gas barrier film
28: support
30: gas barrier layer
30a: organic film
30b: inorganic film

What is claimed is:

1. A method of manufacturing an electronic device comprising:
a drying step of drying a pressure sensitive adhesive layer of a composite film which has the pressure sensitive adhesive layer, a first film bonded to one surface of the pressure sensitive adhesive layer, and a second film bonded to a surface of the pressure sensitive adhesive layer on the opposite side to the first film and in which a moisture vapor transmission rate of the first film at a temperature of 40° C. and a relative humidity of 90% is 100 g/(m²·day) or greater;
a peeling step of peeling the first film from the composite film in which the pressure sensitive adhesive layer is dried; and
a bonding step of bonding the composite film from which the first film is peeled to an electronic device body while facing the pressure sensitive adhesive layer toward the electronic device body.

2. The method of manufacturing an electronic device according to claim 1,
wherein the moisture vapor transmission rate of the second film at a temperature of 40° C. and a relative humidity of 90% is 1×10⁻³ g/(m²·day) or less.

3. The method of manufacturing an electronic device according to claim 1,
wherein a pre-peeling step of peeling the second film from the composite film and a pre-bonding step of bonding a gas barrier film to the pressure sensitive adhesive film of the composite film from which the second film is peeled are performed between the drying step and the peeling step, and
the peeling step is performed on the composite film to which the gas barrier film is bonded.

4. The method of manufacturing an electronic device according to claim 3,
wherein the moisture vapor transmission rate of the gas barrier film at a temperature of 40° C. and a relative humidity of 90% is 1×10⁻³ g/(m²·day) or less.

5. The method of manufacturing an electronic device according to claim 1,
wherein the electronic device body is an organic EL device body obtained by forming an organic EL element on a base.

6. A composite film comprising:
a pressure sensitive adhesive layer;
a first film bonded to one surface of the pressure sensitive adhesive layer; and
a second film bonded to a surface of the pressure sensitive adhesive layer on the opposite side to the first film,
wherein a moisture vapor transmission rate of the first film at a temperature of 40° C. and a relative humidity of 90% is 100 g/(m²·day) or greater.

7. The composite film according to claim 6,
wherein the moisture vapor transmission rate of the second film at a temperature of 40° C. and a relative humidity of 90% is 1×10⁻³ g/(m²·day) or less.

8. The composite film according to claim 6,
wherein the second film includes a support and at least one combination of a gas barrier film and a smoothing film serving as a base of the gas barrier film, which is formed on the support.

9. The composite film according to claim 8,
wherein the gas barrier film is formed of any one of a nitride, an oxide, and an oxynitride.

10. The composite film according to claim 6,
wherein the first film includes a base film and a peeling layer formed on one surface of the base film.

11. The composite film according to claim 10,
wherein the base film is a triacetyl cellulose film, and
the peeling layer has polydimethylsiloxane as a main component.
